(19) United States
(12) Patent Application Publication
(10) Pub. No.: US 2026/0322038 A1
(43) Pub. Date: Oct. 15, 2026

(54) PADDLE DEVICE

(71) Applicant: JPC CONNECTIVITY INC., New Taipei City (TW)

(72) Inventors: Wen-Yu WANG, New Taipei City (TW); Zhong-Lin LI, New Taipei City (TW); Ting-Yu YANG, New Taipei City (TW)

(73) Assignee: JPC CONNECTIVITY INC., New Taipei City (TW)

(21) Appl. No.: 19/567,565

(22) Filed: Mar. 16, 2026

(30) Foreign Application Priority Data
Apr. 9, 2025 (TW) 114113422

(51) Int. Cl. H01R 13/6461; H01R 13/66

(52) U.S. Cl. CPC H01R 13/6461; H01R 13/6658

(57) ABSTRACT

A paddle device includes a main board, a first signal pair, and a second signal pair. The main board includes a surface layer and a specific layer disposed on a different plane from the surface layer. The first signal pair includes a pair of first trace sections and a plurality of first terminals, the first terminals are respectively disposed on two terminals of each of the pair of first trace sections, and the pair of first trace sections and the first terminals are disposed on the surface layer. The second signal pair includes a pair of second trace sections and a plurality of second terminals, the second terminals are respectively disposed on two terminals of each of the pair of second trace sections, the second terminals are disposed on the surface layer, and the pair of second trace sections are disposed on the specific layer.

### CROSS-REFERENCE TO RELATED APPLICATION

This application claims benefit of priority to Taiwanese Patent Application No. 114113422 filed Apr. 9, 2025, the entire contents of which are incorporated herein by reference.

### BACKGROUND

### Technical Field

The present disclosure relates to a paddle device, and more particularly to a paddle device for transmitting high-speed signals.

### Description of Related Art

The statements in this section merely provide background information related to the present disclosure and do not necessarily constitute prior art.

With the development of data centers and high-performance computing systems, the demand for riser cables in data centers and high-performance computing systems is increasing. However, existing high-speed cable modules often suffer from problems such as signal loss, crosstalk, and insufficient heat dissipation performance when facing high-speed data transmission and high-density wiring. In addition, space limitations and assembly difficulties also restrict the widespread application of existing technologies.

Furthermore, referring to FIG. 1, the wiring method of a paddle device 2 of the high-speed cable module is that the surface differential pairs are closely paralleled. However, such a wiring method will cause crosstalk to the high-speed cable module, especially resulting in poor far-crosstalk characteristics. In high-speed and high-frequency transmission, crosstalk will have a significant impact on the eye diagram, especially in PAM4 (four-level pulse amplitude modulation) signals. Crosstalk will cause the voltage amplitude of the signal to decrease and the jitter to increase, thereby narrowing the vertical and horizontal openings of the eye diagram. Since the interval between each voltage layer of the PAM4 signal is narrower, higher signal integrity requirements are placed on it. Therefore, crosstalk may cause the bit error rate to increase and reduce the reliability of data transmission.

Therefore, how to design a paddle device to improve crosstalk has become a critical topic in this field.

### SUMMARY

An objective of the present disclosure is to provide a paddle device, and the paddle device is used to transmit high-speed signals. The paddle device includes a main board, a first signal pair, and a second signal pair.

The main board includes a surface layer and a specific layer disposed on a different plane from the surface layer. The first signal pair includes a pair of first trace sections and a plurality of first terminals. The plurality of first terminals are respectively disposed on two terminals of each of the pair of first trace sections, and the pair of first trace sections and the plurality of first terminals are disposed on the surface layer. The second signal pair includes a pair of second trace sections and a plurality of second terminals. The plurality of second terminals are respectively disposed on two terminals of each of the pair of second trace sections, the plurality of second terminals are disposed on the surface layer, and the pair of second trace sections disposed on the specific layer.

In one embodiment, the main board includes a ground layer. The ground layer is disposed on a different plane from the specific layer and the surface layer, and the first signal pair and the second signal pair are not disposed on the ground layer.

In one embodiment, a cross-layer intersection angle between the first signal pair and the second signal pair is 0 to 180 degrees.

In one embodiment, when the cross-layer intersection angle between the first signal pair and the second signal pair is 0 degree or 180 degrees, the specific layer is disposed between the ground layer and the surface layer.

In one embodiment, the ground layer is disposed between the surface layer and the specific layer.

In one embodiment, the main board is a six-layer board; a first layer and a sixth layer of the main board are two surface layers and the first signal pair and the plurality of second terminals are disposed on the two surface layers; a third layer and a fifth layer of the main board are two specific layers and the pair of second trace sections are disposed on the two specific layers; a second layer and a fourth layer of the main board are the ground layers; wherein a first angle is between the first signal pair on the first layer and the second signal pair on the third layer, and a second angle is between the first signal pair on the sixth layer and the second signal pair on the fifth layer, and the first angle is different from the second angle.

In one embodiment, the plurality of first terminals on at least one terminal of the pair of first trace sections extend to form a pair of first signal terminals, the plurality of second terminals of the second signal pair on the same side as the pair of first signal terminals extend to form a pair of second signal terminals, and the pair of first signal terminals and the pair of second signal terminals are configured for an external device to be plugged in.

In one embodiment, the main board further includes two pairs of conductive holes. The pairs of conductive holes penetrate the surface layer and the specific layer so that the two terminals of the pair of second trace sections are electrically connected to the corresponding second terminals respectively.

In one embodiment, the main board further includes a pair of ground terminals and a ground region. The a pair of ground terminals are disposed on the surface layer, and disposed on two sides of the plurality of second terminals of at least one terminal of the pair of second trace sections respectively. The ground region is disposed on the surface layer, and electrically connected to the pair of ground terminals. The pair of ground terminals and the ground region surround the plurality of second terminals.

In one embodiment, the main board further includes a ground region. The ground region is disposed on the specific layer, and surrounds the pair of second trace sections.

The main purpose and effect of the present disclosure is that the paddle device of the present disclosure has a cross-layer structure in which the first signal pair and the second signal pair are respectively disposed on different layers of the paddle device to reduce the crosstalk caused by each other so as to achieve the effect of significantly improving the crosstalk.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a wiring structure diagram of a surface layer of a conventional paddle device.

FIG. 2 is a structural appearance diagram of a high-speed cable module for transmitting high-speed signals according to the present disclosure.

FIG. 3 is a structural appearance diagram of a paddle device for transmitting high-speed signals according to the present disclosure.

FIG. 4A is a wiring structure diagram of a surface layer of the paddle device according to a first embodiment of the present disclosure.

FIG. 4B is a wiring structure diagram of a specific layer of the paddle device according to a first embodiment of the present disclosure.

FIG. 4C is a schematic diagram of a cross-layer structure of the paddle device according to a first embodiment of the present disclosure.

FIG. 4D is a wiring structure diagram of a ground layer of the paddle device according to a first embodiment of the present disclosure.

FIG. 4E is a cross-sectional view of a main board along a direction from a first conductive hole to a second conductive hole according to a first embodiment of the present disclosure.

FIG. 5A is a comparison diagram of crosstalk of a first signal pair when a conventional paddle device and the first embodiment of the paddle device of the present disclosure perform signal transmission.

FIG. 5B is a comparison diagram of crosstalk of a second signal pair when the conventional paddle device and the first embodiment of the paddle device of the present disclosure perform signal transmission.

FIG. 6A is a wiring structure diagram of the surface layer of the paddle device according to a second embodiment of the present disclosure.

FIG. 6B is a wiring structure diagram of the specific layer of the paddle device according to a second embodiment of the present disclosure.

FIG. 6C is a schematic diagram of a cross-layer structure of the paddle device according to a second embodiment of the present disclosure.

FIG. 6D is a wiring structure diagram of a ground layer of the paddle device according to a second embodiment of the present disclosure.

### DETAILED DESCRIPTION

Reference will now be made to the drawing figures to describe the present disclosure in detail. It will be understood that the drawing figures and exemplified embodiments of present disclosure are not limited to the details thereof.

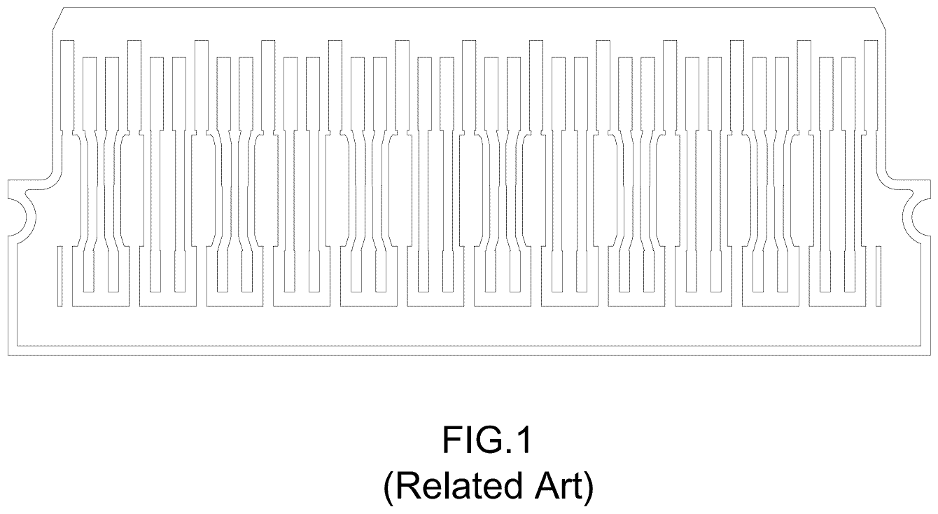

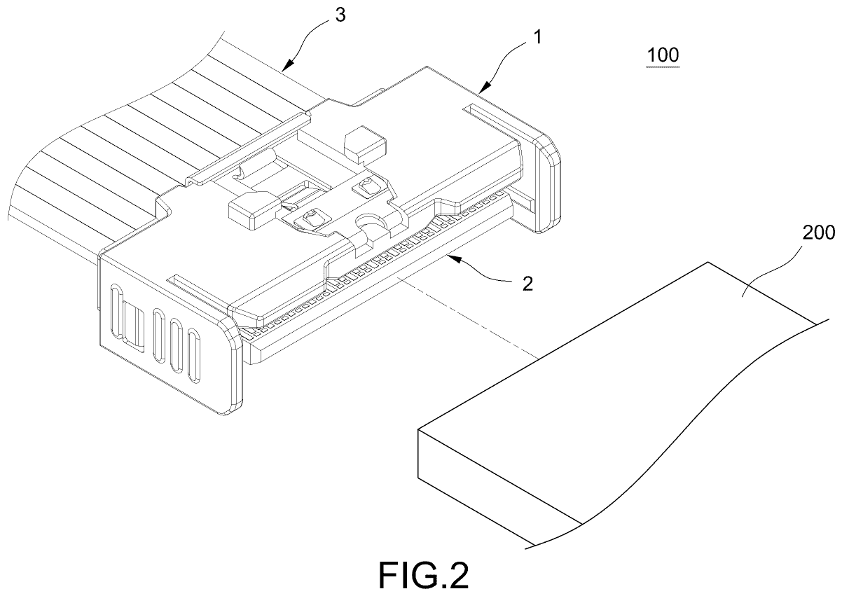

Please refer to FIG. 2, which shows a structural appearance diagram of a high-speed cable module for transmitting high-speed signals according to the present disclosure, and also refer to FIG. 1. The high-speed cable module 100 of the present disclosure may be, for example but not limited to, a high-speed cable module 100 such as MCIO (mini cool edge IO) that can be used to transmit high-speed signals, and the high-speed cable module 100 is used to plug into a connector (not shown) of an external device 200 (for example but not limited to, a server main board, a storage device, etc.). The high-speed cable module 100 includes components such as a connector 1, a paddle device 2, and a cable 3. These components are formed into the high-speed cable module 100 by welding and assembly, and the paddle device 2 generally has differential pairs (i.e., closely parallel trace) disposed on the surface, but is not limited to this. It may also be a non-differential pair trace and may be disposed according to actual requirements.

Furthermore, the high-speed cable module 100 is widely used in high-density connection systems to achieve high-speed data transmission and stable signal integrity. In particular, the present disclosure involves cable assembly technology in the field of data centers and high-performance computing systems, specifically targeting the structural design and performance optimization of the paddle device 2 to increase the performance of the paddle device 2 in terms of space utilization, reliability, and transmission performance, and is particularly suitable for high-speed interconnection scenarios such as server main boards, storage devices, and PCIe.

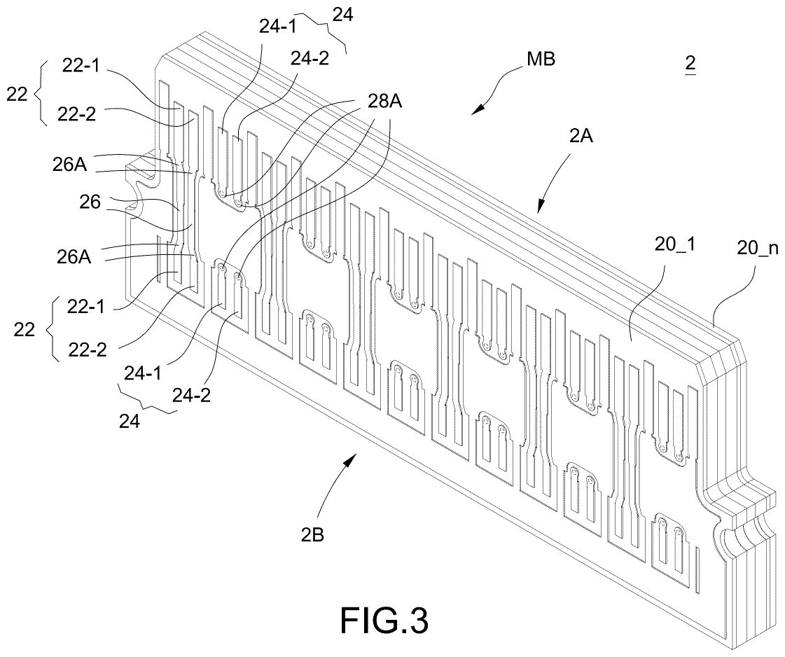

Please refer to FIG. 3, which shows a structural appearance diagram of a paddle device for transmitting high-speed signals according to the present disclosure, and also refer to FIG. 2. The paddle device 2 is used for transmitting high-speed signals, and the paddle device 2 includes a main board MB, a first signal pair 26, and a second signal pair 28. The main board MB is a multi-layer board, and the first signal pair 26 and the second signal pair 28 are disposed on at least one surface layer 20-1, 20-n (a surface layer 20-1 is used as an example) of the paddle device 2. Specifically, the first signal pair 26 includes a pair of first trace sections and a plurality of first terminals 26A. The plurality of first terminals 26A are respectively disposed on two terminals (i.e., two pair of first terminals 26A) of each of the pair of first trace sections, and the pair of first trace sections and the plurality of first terminals 26A are disposed on the surface layer 20-1. The second signal pair 28 includes a pair of second trace sections (not shown) and a plurality of second terminals 28A. The plurality of second terminals 28A are respectively disposed on two terminals (i.e., two pair of second terminals 28A) of each of the pair of second trace sections (not shown). The plurality of second terminals 28A are also disposed on the surface layer 20-1, and the pair of second trace sections (not shown) are not disposed on the surface layer 20-1, are electrically connected to the plurality of second terminals 28A.

In FIG. 3, the plurality of first terminals 26A on at least one terminal of the pair of first trace sections extend to form a pair of first signal terminals 22. Here, two pairs of first terminals 26A form the first signal terminals 22, and the first signal terminals 22 and the first terminals 26A described below may represent the same object. The distinction between the two is only for convenience of illustration and will not be repeated in the following text. The plurality of second terminals 28A of at least one terminal of the pair of second trace sections (not shown) also extend to form a pair of second signal terminals 24. Here, two pairs of second terminals 28A form the second signal terminals 24, and the second signal terminals 24 and the second terminals 28A described below may represent the same object. The distinction between the two is only for convenience of illustration and will not be repeated in the following text. When the first terminals 26A and the second terminals 28A on only one side form the first signal terminals 22 and the second signal terminals 24, the two are disposed on the same side of the main board MB. Please refer to FIG. 2, the first signal terminals 22 and the second signal terminals 24 are disposed on the same side of the main board MB and may be used as edge connectors (i.e., gold fingers) for plugging in the external device 200. In another embodiment, the first terminals 26A and the second terminals 28A on the other side may also form a signal terminal structure to serve as a relay board, or form a soldering pad or a larger soldering area. The above structures are all conducive to the welding of the cable 3. Furthermore, when the two pairs of first terminals 26A and the two pairs of second terminals 28A are extended to form the first signal terminals 22 and the second signal terminals 24 respectively, the first signal terminals 22 and the second signal terminals 24 are both disposed on the surface layer 20-1 of the main board MB. A pair of first signal terminals 22 and a pair of second signal terminals 24 are disposed in parallel on a first side 2A of the surface layer 20-1 of the paddle device 2. Furthermore, the other pair of first signal terminals 22 and the other pair of second signal terminals 24 are disposed in parallel on a second side 2B of the surface layer 20-1 of the paddle device 2.

Taking a differential pair as an example, each pair of first signal terminals 22 includes a first terminal 22-1 and a second terminal 22-2 of the differential pair, and each pair of second signal terminals 24 includes a third terminal 24-1 and a fourth terminal 24-2 of the differential pair. In particular, the first terminal 22-1 and the second terminal 22-2 are arranged in parallel, and the third terminal 24-1 and the fourth terminal 24-2 are arranged in parallel. In particular, the first side 2A may be a side for plugging the external device 200, and the second side 2B may be a side for welding the cable 3. In one embodiment, the second side 2B is preferably substantially parallel to the first side 2A, but is not limited thereto, that is, the first side 2A and the second side 2B may be any two sides of the main board MB.

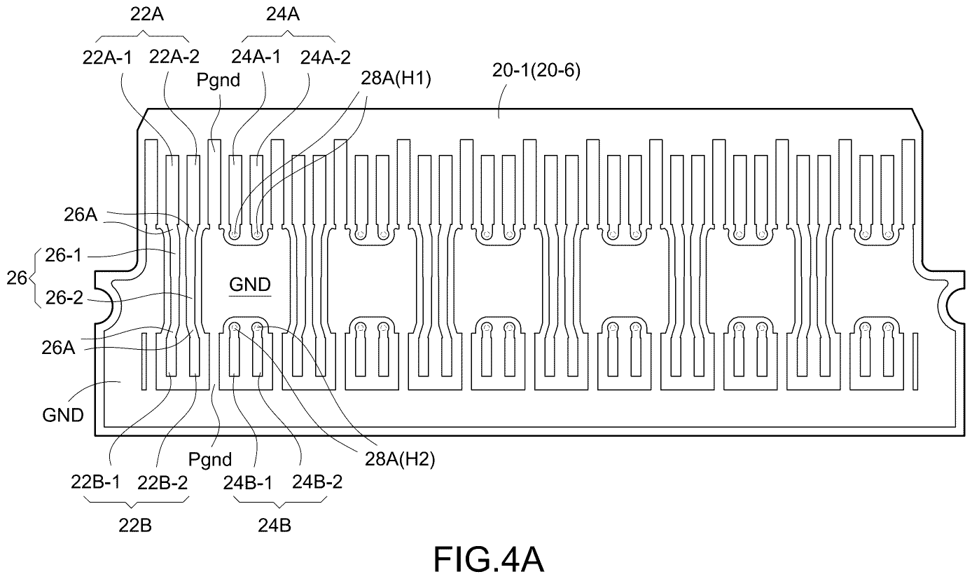

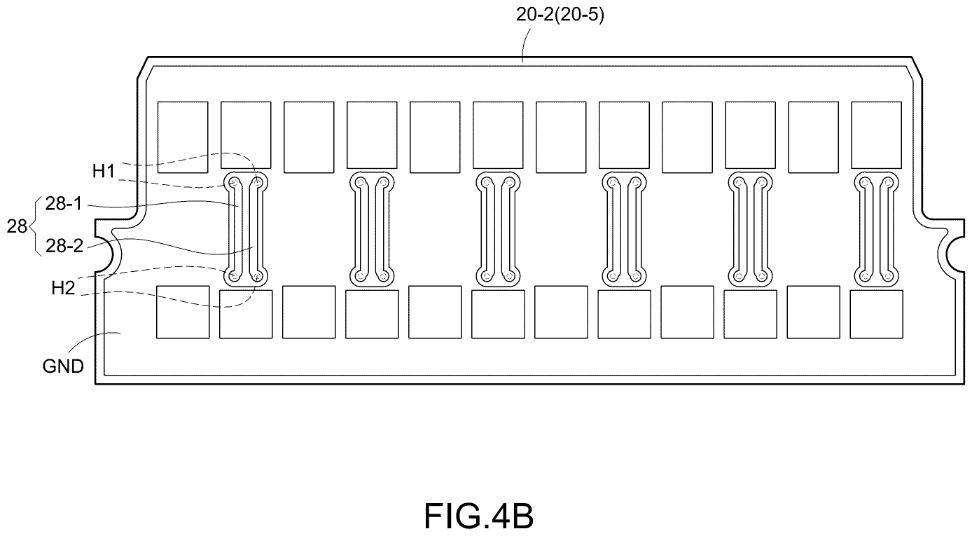

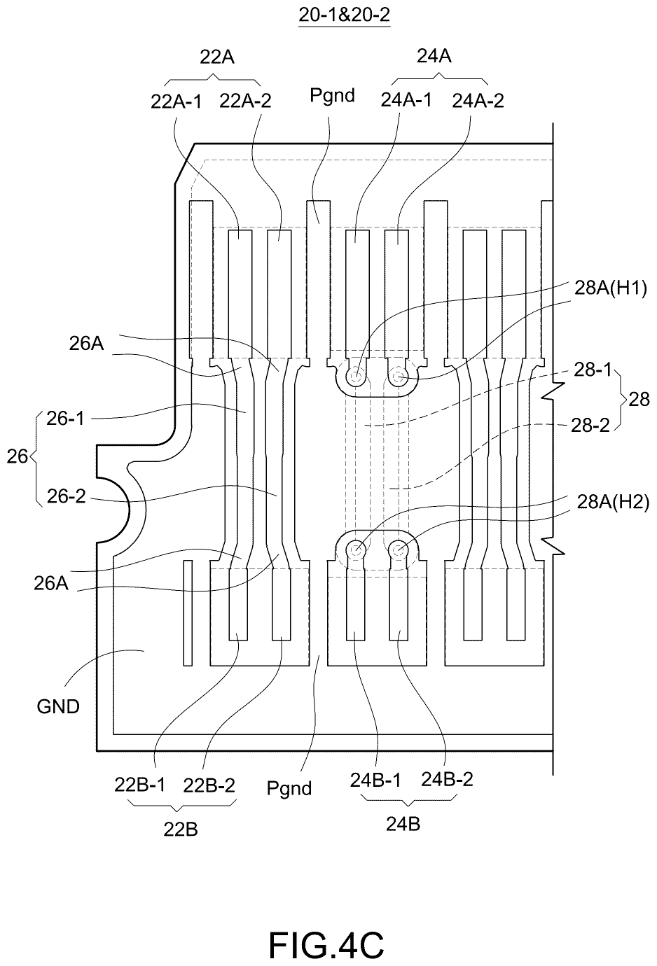

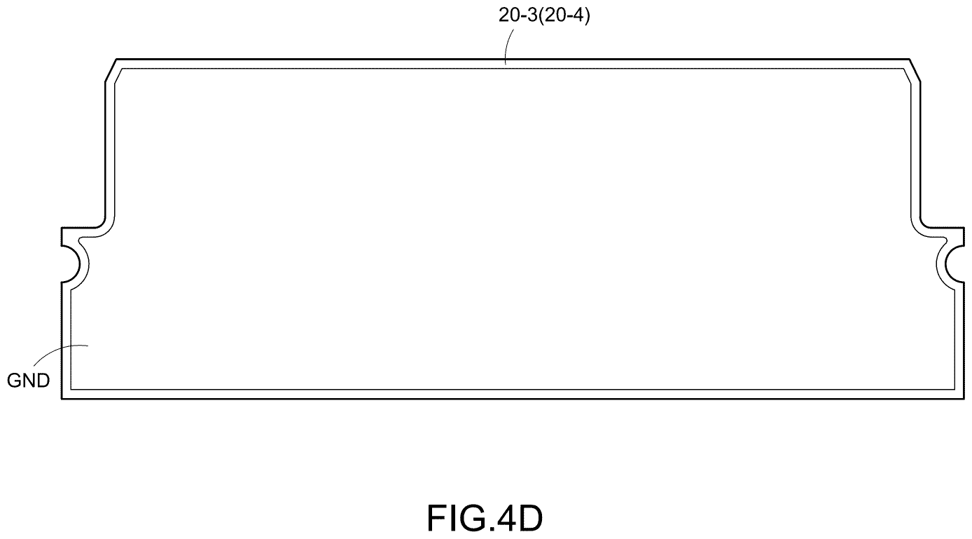

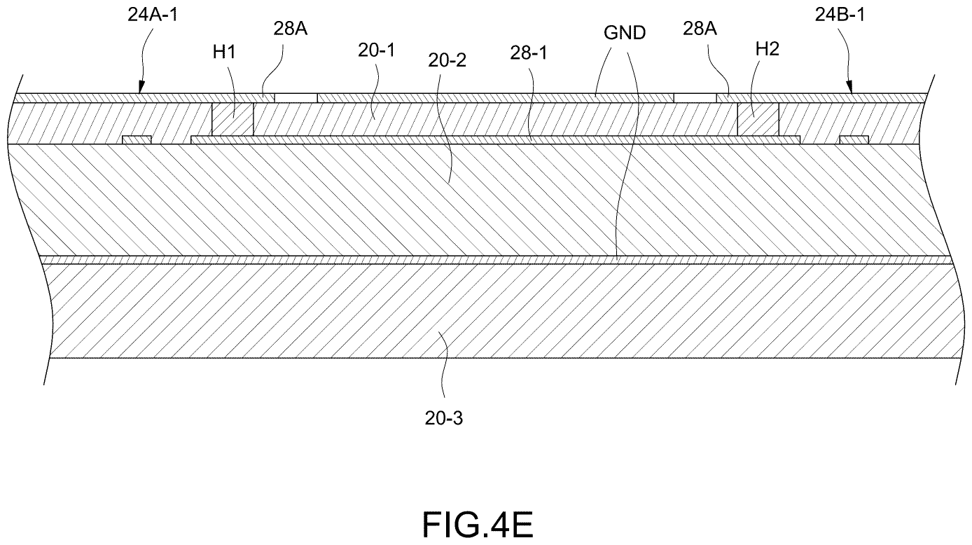

Please refer to FIG. 4A, which shows a wiring structure diagram of a surface layer of the paddle device according to a first embodiment of the present disclosure; please refer to FIG. 4B, which shows a wiring structure diagram of a specific layer of the paddle device according to a first embodiment of the present disclosure, and also refer to FIG. 2 and FIG. 3. In FIG. 4A and FIG. 4B, for simplicity and convenience in describing the features of the present disclosure, one first signal pair 26 and one second signal pair 28 are used for description. The first signal pair 26 and the second signal pair 28 that are subsequently extended have the same structure and are disposed in the same manner. In addition, in one embodiment, the word “substantially” described in the present disclosure may be expressed as “essentially” and may have a deviation of, for example but not limited to, 5-10%. For example, two components being “substantially parallel” may be considered as two components being “essentially parallel”, but there may be an angle difference of 5-10%, and so on.

In FIG. 4A, the paddle device 2 includes the first signal pair 26, and the first signal pair 26 is disposed on the surface layer 20-1. A first terminal 26A of one terminal of the first signal pair 26 can be extended to form one pair of first signal terminals 22A, and a first terminal 26A of the other terminal of the first signal pair 26 can be extended to form the other pair of first signal terminals 22B. Taking a differential pair as an example, the first trace sections of the first signal pair 26 may include a first trace 26-1 and a second trace 26-2. The first terminals 26A at both terminals of the first trace 26-1 extend to respectively form a first terminal 22A-1 and a first terminal 22B-1, and the first terminals 26A at both terminals of the second trace 26-2 extend to respectively form a second terminal 22A-2 and a second terminal 22B-2. An electrically isolated area is included between the first trace 26-1 and the second trace 26-2, and the area may be a hollow area or filled with a non-conductive material (such as but not limited to, resin, etc.). In particular, the first trace 26-1 and the second trace 26-2 may be a substantially parallel trace structure, with only a slight bend at the electrical connection terminals 22A-1, 22A-2, 22B-1, 22B-2, but it does not exclude that it may include compensation-related trace patterns such as serpentine traces, and the first trace 26-1 and the second trace 26-2 may preferably be disposed in a mirror image along the midpoint line between the two.

On the other hand, in FIG. 4A, one pair of second signal terminals 24A is disposed on the same side of one pair of first signal terminals 22A and is disposed in parallel with one pair of first signal terminals 22A. The other pair of second signal terminals 24B is disposed on the same side of the other pair of first signal terminals 22B and is disposed in parallel with the other pair of first signal terminals 22B. In FIG. 4B, the paddle device 2 includes a second signal pair 28 and two pairs of conductive holes, and the second signal pair 28 is disposed on a specific layer 20-2 (illustrated as the second layer, but not limited thereto). The two pairs of conductive holes are used to penetrate the surface layer 20-1 and the specific layer 20-2 of the paddle device 2, and the two pairs of conductive holes include a first conductive hole H1 and a second conductive hole H2. The first conductive hole H1 and the second conductive hole H2 are respectively disposed in the second terminals 28A at both terminals of the second signal pair 28. In particular, the second terminals 28A at one terminal is electrically connected to one terminal of the second trace sections on the specific layer 20-2 through the first conductive hole H1, and the second terminals 28A at the other terminal is electrically connected to the other terminal of the second trace sections on the specific layer 20-2 through the second conductive hole H2. Therefore, the two pairs of conductive holes are mainly used to electrically connect the two terminals of the second trace sections to the corresponding second terminals 28A respectively.

A second terminal 28A of one terminal of the second signal pair 28 can be extended to form one pair of second signal terminals 24A, and a second terminal 28A of the other terminal of the second signal pair 28 can be extended to form the other pair of second signal terminals 24B. Taking a differential pair as an example, the second trace sections of the second signal pair 28 may include a third trace 28-1 and a fourth trace 28-2. The second terminals 28A at both terminals of the third trace 28-1 extend to respectively form a third terminal 24A-1 and a third terminal 24B-1, and the second terminals 28A at both terminals of the fourth trace 28-2 extend to respectively form a fourth terminal 24A-2 and a fourth terminal 24B-2. It is similar to the first signal pair 26, an electrically isolated area is included between the third trace 28-1 and the fourth trace 28-2, and the third trace 28-1 and the fourth trace 28-2 may be a substantially parallel trace structure, and the third trace 28-1 and the fourth trace 28-2 may preferably be disposed in a mirror image along the midpoint line between the two.

Please refer to FIG. 4C, which shows a schematic diagram of a cross-layer structure of the paddle device according to a first embodiment of the present disclosure, and also refer to FIG. 2 to FIG. 4B. The first signal pair 26 and the second signal pair 28 are in a structure that is substantially parallel to each other across layers, and a straight line connecting the first signal terminals 22A, 22B is substantially parallel to a straight line connecting the second signal terminals 24A, 24B. In other words, if the main board MB is viewed from a bird's eye view (top view), the first signal pair 26 on the surface layer 20-1 and the second signal pair 28 on the surface layer 20-1 or on the specific layer 20-2 are substantially parallel to each other. Taking a differential pair as an example, the first wire 26-1, the second wire 26-2, the third wire 28-1, and the fourth wire 28-2 are substantially parallel to each other across layers. Therefore, the straight lines connecting the first terminals 22A-1, 22B-1 and the third terminals 24A-1, 24B-1 are substantially parallel to each other, and the straight lines connecting the second terminals 22A-2, 22B-2 and the fourth terminals 24A-2, 24B-2 are substantially parallel to each other. Since the second signal pair 28 is disposed on the specific layer 20-2, the surface layer 20-1 of the main board MB can reduce the crosstalk between the first signal pair 26 and the second signal pair 28 by an interleaved arrangement of the first signal pair 26 and a ground region GND so that the crosstalk can be greatly improved.

On the other hand, two pairs of ground terminals Pgnd and the ground region GND may be further provided on the surface layer 20-1 of FIG. 4A. The two pairs of ground terminals Pgnd are respectively disposed on two sides of the two pairs of second signal terminals 24A, 24B (i.e., the second signal terminals 24A, 24B formed by the two pairs of second terminals 28A) so that the second signal terminals 24A, 24B and the first signal terminals 22A, 22B are isolated from each other through the ground terminals Pgnd. The ground region GND is electrically connected to the ground terminals Pgnd, and the ground terminals Pgnd and the ground region GND surround the second signal terminals 24A, 24B so that the ground terminals Pgnd, the ground region GND, and the second signal terminals 24A, 24B are electrically isolated. Specifically, in the surface layer 20-1 of FIG. 4A, the area outside the first signal pair 26, the first signal terminals 22A, 22B, the second signal terminals 24A, 24B, and the second terminal 28A may be disposed to ground (i.e., the ground terminals Pgnd and the ground region GND), and the ground terminals Pgnd, the ground region GND, and the above-mentioned components are electrically isolated. On the other hand, the surface layer 20-1 may only have a pair of ground terminals Pgnd disposed in parallel with the second signal terminal 24A or the second signal terminal 24B so as to be electrically connected to the ground terminals Pgnd through the ground region GND and surround the second signal terminal 24A or the second signal terminal 24B. In particular, the electrically isolated area may be a hollow area or filled with a non-conductive material (such as but not limited to, resin, etc.). Therefore, the crosstalk between the first signal pair 26 and the second signal pair 28 can be further reduced by disposing the first signal pair 26 and the second signal pair 28 in parallel across layers so that the crosstalk can be greatly improved.

In one embodiment, the ground region GND of FIG. 4B is disposed in a manner similar to that of FIG. 4A, except that the ground region GND is disposed in a region outside the second signal pair 28 on the specific layer 20-2 and surrounds the second signal pair 28, and can also achieve a similar effect to that of FIG. 4A. Please refer to FIG. 4A and FIG. 4B, the areas of the first signal terminals 22A, 22B and the second signal terminals 24A, 24B may be electrically isolated areas without copper plating, but the present disclosure is not limited thereto. In addition, please refer to FIG. 4D, which shows a wiring structure diagram of a ground layer of the paddle device according to a first embodiment of the present disclosure, and refer to FIG. 2 to FIG. 4C. In FIG. 4D, one layer of the paddle device 2 may be disposed as a ground layer 20-3 (illustrated as the third layer, but not limited thereto), and the ground layer 20-3 is on a different plane from the specific layer 20-2 and the surface layer 20-1. The ground layer 20-3 may be provided with a large area of copper to serve as a large area of ground region GND. Furthermore, on the ground layer 20-3, the paddle device 2 is not provided with the first signal pair 26 and the second signal pair 28 so as to reduce signal interference, signal loss, and instability of the paddle device 2.

On the other hand, please refer to FIG. 4E, which shows a cross-sectional view of a main board along a direction from a first conductive hole to a second conductive hole according to a first embodiment of the present disclosure, and also refer to FIG. 2 to FIG. 4. In FIG. 4E, it mainly shows a cross section of the main board MB along the direction of the third terminal 24A-1, the first conductive hole H1, the second conductive hole H2, and the third terminal 24B-1. The first conductive hole H1 and the second conductive hole H2 are mainly a hole (also called a blind hole or via) that penetrates through between the surface layer 20-1 and the specific layer 20-2 of the main board MB, and are made conductive by filling conductive materials (such as but not limited to, copper, tin, etc.). Therefore, the third terminal 24A-1 (formed by extending the second terminal 28A) disposed outside the surface layer 20-1 may be electrically connected to one terminal of the third trace 28-1 of the specific layer 20-2 through the first conductive hole H1, and the third terminal 24B-1 (formed by extending the second terminal 28A) may also be electrically connected to the other terminal of the third trace 28-1 of the specific layer 20-2 through the second conductive hole H2. The cross-sectional structure of the fourth wire 28-2 is similar to this, and will not be described in detail herein. In addition, since the ground layer 20-3 is provided with a large area of copper plating, it has a large area of ground region GND.

In one embodiment, when the paddle device 2 has only one surface layer 20-1 provided with the first signal terminals 22A, 22B, the second signal terminals 24A, 24B, the first signal pair 26, and the second terminal 28A, the ground layer 20-3 may be disposed between the surface layer 20-1 and the specific layer 20-2, or the specific layer 20-2 may be disposed between the surface layer 20-1 and the ground layer 20-3. On the contrary, when the two surface layers 20-1, 20-n of the paddle device 2 are respectively provided with the first signal terminals 22A, 22B, the second signal terminals 24A, 24B, the first signal pair 26, and the second terminal 28A, the ground layer 20-3 must isolate the first signal terminals 22A, 22B, the second signal terminals 24A, 24B, the first signal pair 26, and the second terminal 28A on the two surface layers 20-1, 20-n, and the second signal pair 28 on different layers to avoid mutual interference between the signals transmitted by the first signal pair 26 and the second signal pair 28. Therefore, when the two surface layers 20-1, 20-n of the paddle device 2 are respectively provided with the first signal terminals 22A, 22B, the second signal terminals 24A, 24B, the first signal pair 26, and the second terminal 28A, two ground layers 20-3 are required to isolate the high-speed signals.

Specifically, when the two surface layers 20-1, 20-n of the paddle device 2 are respectively provided with the first signal terminals 22A, 22B, the second signal terminals 24A, 24B, the first signal pair 26, and the second terminal 28A, the paddle device 2 needs to use a board with more than six layers. Taking the circuit structure of FIG. 4A to FIG. 4D on a six-layer board as an example. The first layer 20-1 and the sixth layer 20-6 of the paddle device 2 are respectively provided with the first signal terminals 22A, 22B, the second signal terminals 24A, 24B, the first signal pair 26, and the second terminal 28A (see FIG. 4A), and the second layer 20-2 and the fifth layer 20-5 of the paddle device 2 are specific layers and are respectively provided with the second signal pair 28. The second signal pair 28 is electrically connected to the second terminal 28A (see FIG. 4B) through the first conductive hole H1 and the second conductive hole H2 penetrating the two surface layers 20-1, 20-n. Furthermore, the third layer 20-3 and the fourth layer 20-4 of the paddle device 2 are ground layers (see FIG. 4D) to isolate high-speed signals transmitted on the surface layer 20-1, the second layer 20-2, the surface layer 20-6, and the fifth layer 20-5. In one embodiment, the reference numbers of all components in the signal pair are merely a structural labeling numbers for convenience of illustration and has nothing to do with the type and waveform of the signal transmission. For example, the signals transmitted by the first signal terminals 22A, 22B of the first layer 20-1 may be completely different from the signals transmitted by the second signal terminals 24A, 24B of the first layer 20-1, and the signals transmitted by the first signal terminals 22A, 22B of the first layer 20-1 may also be completely different from the signals transmitted by the first signal terminals 22A, 22B of the sixth layer 20-6. Furthermore, referring to FIG. 4A, the signals transmitted by the first signal terminals 22A, 22B on the same layer may be completely different. However, this is not limited to the above, and the same signal can be transmitted according to actual requirements, and so on, which will not be repeated here.

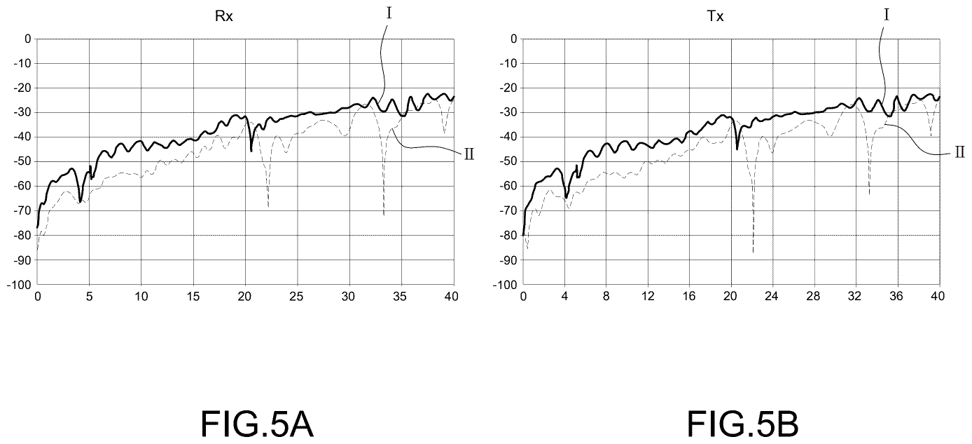

Please refer to FIG. 5A, which shows a comparison diagram of crosstalk of a first signal pair when a conventional paddle device and the first embodiment of the paddle device of the present disclosure perform signal transmission; please refer to FIG. 5B, which shows a comparison diagram of crosstalk of a second signal pair when the conventional paddle device and the first embodiment of the paddle device of the present disclosure perform signal transmission, and also refer to FIG. 1 to FIG. 4E. The waveform I (solid line) in FIG. 5A and FIG. 5B is mainly a waveform curve when the Rx and Tx signals are transmitted using the trace structure of the conventional paddle device 2 in FIG. 1. The waveform II (dashed line) in FIG. 5A and FIG. 5B is mainly a waveform curve when the first signal pair 26 and the second signal pair 28 of the paddle device 2 of the present disclosure are used to transmit the Rx and Tx signals. Moreover, it can be clearly seen from FIG. 5A and FIG. 5B that the use of the trace structure disclosed in the present disclosure can reduce the crosstalk of the Rx signal by more than 10 dB when the paddle device 2 transmits the Rx and Tx signals simultaneously.

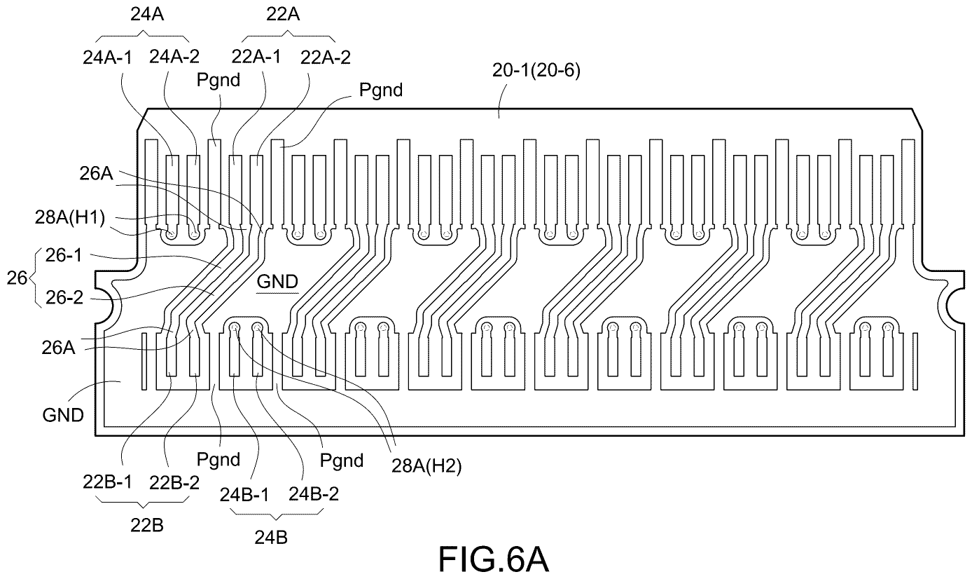

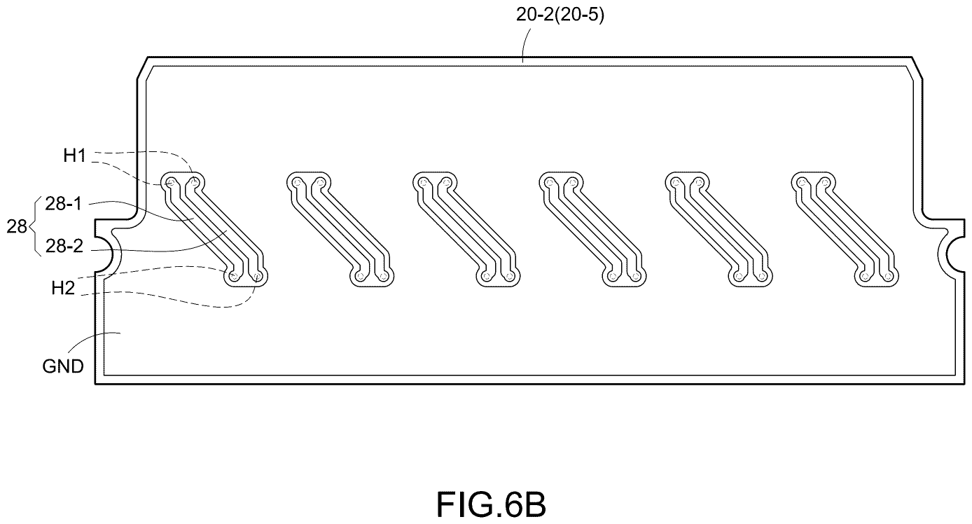

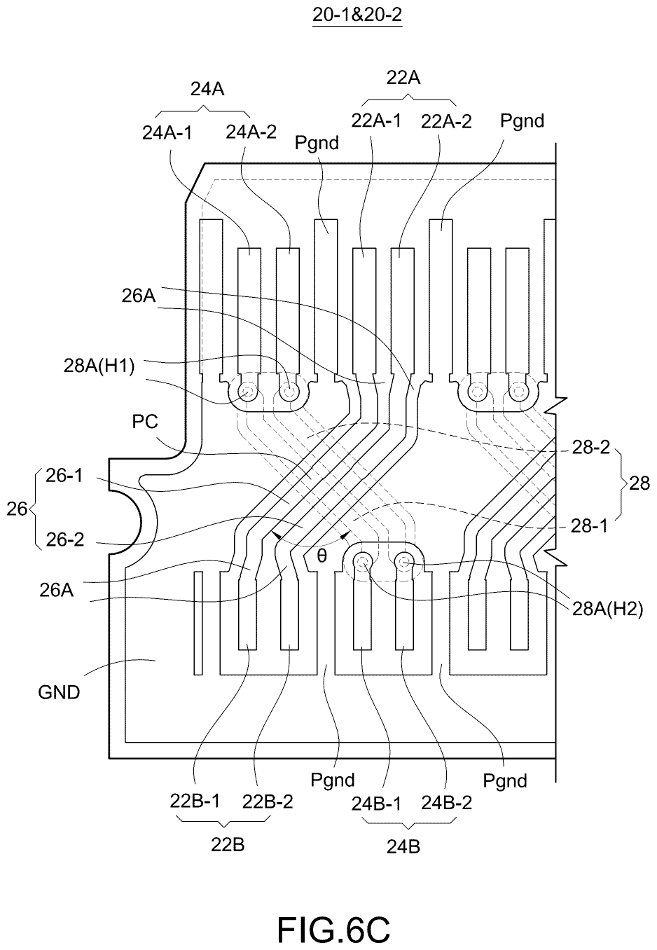

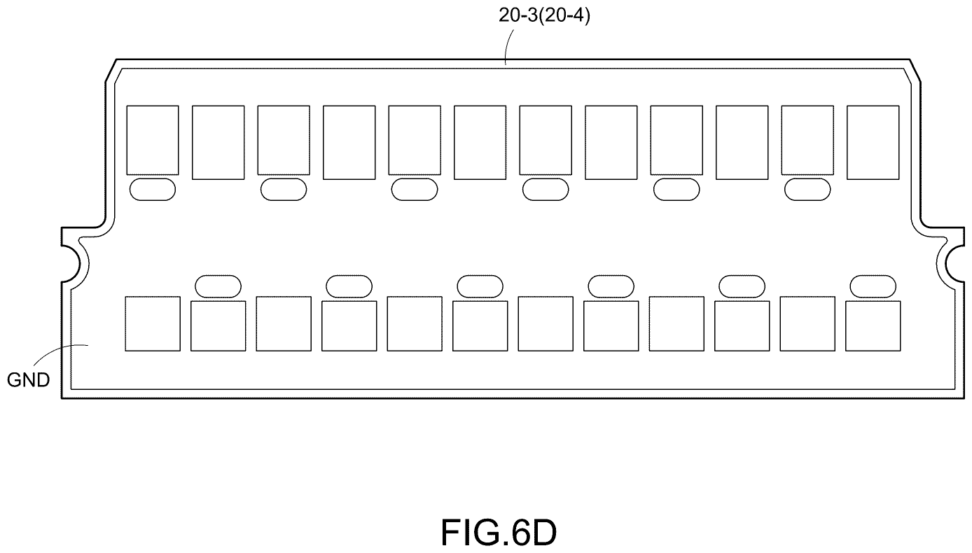

Please refer to FIG. 6A, which shows a wiring structure diagram of the surface layer of the paddle device according to a second embodiment of the present disclosure; please refer to FIG. 6B, which shows a wiring structure diagram of the specific layer of the paddle device according to a second embodiment of the present disclosure, and also refer to FIG. 2 to FIG. 5B. The trace structures of FIG. 6A and FIG. 6B are similar to those of FIG. 4A and FIG. 4B, except that the cross layers of the first signal pair 26 and the second signal pair 28. Specifically, the first terminals 26A at both terminals of the first signal pair 26 in FIG. 6A and FIG. 6B are misaligned so that the positions of the first signal terminal 22A and the second signal terminal 24A are swapped. Therefore, the straight line connecting the first signal terminal 22A and the second signal terminal 24B is substantially parallel to the straight line connecting the second signal terminal 24A and the first signal terminal 22B. Furthermore, the first terminal 26A of the first signal pair 26 may also be extended to respectively form the first signal terminals 22A, 22B, and the second terminal 28A of the second signal pair 28 may also be extended to respectively form the second signal terminals 24A, 24B.

Therefore, the first signal terminal 22A is electrically connected to the first signal terminal 22B through the secondary bend of the first signal pair 26, and the second signal terminal 24A is also electrically connected to the second signal terminal 24B through the secondary bend of the second signal pair 28. Please refer to FIG. 6C, which shows a schematic diagram of a cross-layer structure of the paddle device according to a second embodiment of the present disclosure, and also refer to FIG. 2 to FIG. 6B. Since the first signal pair 26 and the second signal pair 28 are respectively bent at different layers of the paddle device 2, the first signal pair 26 and the second signal pair 28 include two pairs of intersection points Pc that intersect across layers, and the first signal pair 26 and the second signal pair 28 form a specific angle θ with the intersection points Pc as the center. In particular, the specific angle θ may be 0 to 180 degrees, and the preferred embodiment is 90 degrees, but it is not limited to this. It may also be 45 degrees, 120 degrees, 135 degrees, etc., and it may be adjusted to the optimal angle according to actual conditions, which will not be repeated here. In other words, if the main board MB is viewed from a bird's eye view, the first signal pair 26 disposed on the surface layer 20-1 and the second signal pair 28 disposed on the surface layer 20-1 or on the specific layer 20-2 intersect across layers. In one embodiment, since a magnetic field is generated when a signal is transmitted on a trace (right-hand rule), and if paths of signal transmission happen to intersect vertically, the magnetic field can cancel each other out and reduce the crosstalk caused by each other. Therefore, the angle θ at which the first signal pair 26 and the second signal pair 28 intersect across layers is substantially 90 degrees, which can achieve a better crosstalk reduction effect and is a preferred implementation.

Another difference between FIG. 6B and FIG. 4B is that in the specific layer 20-2(20-5), the area corresponding to the positions of the first signal terminals 22A, 22B and the second signal terminals 24A, 24B may be copper-plated to serve as a large-area ground region GND, and this feature of FIG. 6B and FIG. 4B may be selected for application according to the actual requirements of the paddle device 2. In addition, the difference between FIG. 6D and FIG. 4D is that in the ground layer 20-3(20-4), the area corresponding to the positions of the first signal terminals 22A, 22B, the second signal terminals 24A, 24B, and the second terminal 28A may be used as an electrically isolated area without copper plating, and this feature of FIG. 6D and FIG. 4D may also be selected for application according to the actual requirements of the paddle device 2. Therefore, the paddle device 2 of FIG. 6D also includes a large-area ground layer 20-3(20-4) served as the ground region GND, and may also reduce signal interference, signal loss, and instability of the paddle device 2.

In particular, the crosstalk comparison diagram of the paddle device 2 of the second embodiment may be inferred from FIG. 5A, FIG. 5B, and FIG. 6A to FIG. 6D, and the crosstalk comparison diagram is not specifically shown here. Moreover, since the cross layers of the first signal pair 26 and the second signal pair 28 provide better crosstalk suppression effect, the paddle device 2 of FIG. 6A to FIG. 6D may show better crosstalk reduction effect (i.e., the reduction can be more than 10 dB) than the paddle device 2 of FIG. 4A to FIG. 4D when simultaneously transmitting Rx and Tx signals.

On the other hand, in one embodiment, the circuit structures and trace methods not specifically described in FIG. 6A to FIG. 6D are similar to those in FIG. 4A to FIG. 4E, or may be inferred from FIG. 4A to FIG. 4E, and will not be described in detail herein. In another embodiment, when the paddle device 2 is a six-layer board, the configurations of FIG. 4A to FIG. 4E and FIG. 6A to FIG. 6D may be integrated and applied together. For example but not limited to, the first to third layers are provided with the layer boards of FIG. 4A to FIG. 4E, and the sixth to fourth layers are provided with the layer boards of FIG. 6A to FIG. 6D. Therefore, there should be a first angle (for example but not limited to, 0 degree) between the first signal pair 26 and the second signal pair 28 of the first layer 20-1 and the second layer 20-2 of the main board MB, and there should be a second angle (for example but not limited to, 90 degrees across layers) between the first signal pair 26 and the second signal pair 28 of the sixth layer 20-6 and the fifth layer 20-5. Furthermore, the first angle is different from the second angle so that the paddle device 2 disclosed herein may selectively configure the transmission position according to the signal accuracy requirements (for example but not limited to, signals with high accuracy requirements can transmit through the sixth layer to fourth layer), and so on, which will not be repeated here.

In addition, since the cross payers of the first signal pair 26 and the second signal pair 28 provide a better crosstalk suppression effect, the ground layer of FIG. 6A to FIG. 6D can be configured more flexibly. Specifically, when the angle θ of cross payers of the first signal pair 26 and the second signal pair 28 is similar to that in FIG. 4A to FIG. 4E (i.e., when the angle θ is 0 degree or 180 degrees), the crosstalk suppression effect is relatively small, and therefore it is preferable to dispose the specific layer between the ground layer and the surface layer. On the contrary, when the angle θ of cross payers of the first signal pair 26 and the second signal pair 28 is similar to that in FIG. 6A to FIG. 6D (i.e., the angle θ is not 0 degree or 180 degrees), the crosstalk suppression effect is relatively greater, and therefore it is preferable to dispose the ground layer between the surface layer and the specific layer. Therefore, if the first angle is different from the second angle, and assuming that the first to third layers are provided with the layer boards of FIG. 6A to FIG. 6D, and the sixth to fourth layers are provided with the layer boards of FIG. 4A to FIG. 4E, the structure of the first to third layers is that the ground layer 20-2 is provided between the surface layer 20-1 and the specific layer 20-3, and the structure of the sixth to fourth layers is that the specific layer 20-5 is provided between the ground layer 20-4 and the surface layer 20-6, and so on, which will not be repeated here.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A paddle device configured to transmit high-speed signals, the paddle device comprising:
a main board comprising a surface layer and a specific layer disposed on a different plane from the surface layer,
a first signal pair comprising a pair of first trace sections and a plurality of first terminals, the plurality of first terminals respectively disposed on two terminals of each of the pair of first trace sections, and the pair of first trace sections and the plurality of first terminals disposed on the surface layer, and
a second signal pair comprising a pair of second trace sections and a plurality of second terminals, the plurality of second terminals respectively disposed on two terminals of each of the pair of second trace sections, the plurality of second terminals disposed on the surface layer, and the pair of second trace sections disposed on the specific layer.

2. The paddle device as claimed in claim 1, wherein the main board comprises:
a ground layer disposed on a different plane from the specific layer and the surface layer, and the first signal pair and the second signal pair not disposed on the ground layer.

3. The paddle device as claimed in claim 2, wherein a cross-layer intersection angle between the first signal pair and the second signal pair is 0 to 180 degrees.

4. The paddle device as claimed in claim 2, wherein when the cross-layer intersection angle between the first signal pair and the second signal pair is 0 degree or 180 degrees, the specific layer is disposed between the ground layer and the surface layer.

5. The paddle device as claimed in claim 3, wherein when the cross-layer intersection angle between the first signal pair and the second signal pair is 0 degree or 180 degrees, the specific layer is disposed between the ground layer and the surface layer.

6. The paddle device as claimed in claim 2, wherein the ground layer is disposed between the surface layer and the specific layer.

7. The paddle device as claimed in claim 3, wherein the ground layer is disposed between the surface layer and the specific layer.

8. The paddle device as claimed in claim 2, wherein the main board is a six-layer board; a first layer and a sixth layer of the main board are two surface layers and the first signal pair and the plurality of second terminals are disposed on the two surface layers; a third layer and a fifth layer of the main board are two specific layers and the pair of second trace sections are disposed on the two specific layers; a second layer and a fourth layer of the main board are the ground layers; wherein a first angle is between the first signal pair on the first layer and the second signal pair on the third layer, and a second angle is between the first signal pair on the sixth layer and the second signal pair on the fifth layer, and the first angle is different from the second angle.

9. The paddle device as claimed in claim 3, wherein the main board is a six-layer board; a first layer and a sixth layer of the main board are two surface layers and the first signal pair and the plurality of second terminals are disposed on the two surface layers; a third layer and a fifth layer of the main board are two specific layers and the pair of second trace sections are disposed on the two specific layers; a second layer and a fourth layer of the main board are the ground layers; wherein a first angle is between the first signal pair on the first layer and the second signal pair on the third layer, and a second angle is between the first signal pair on the sixth layer and the second signal pair on the fifth layer, and the first angle is different from the second angle.

10. The paddle device as claimed in claim 1, wherein the plurality of first terminals on at least one terminal of the pair of first trace sections extend to form a pair of first signal terminals, the plurality of second terminals of the second signal pair on the same side as the pair of first signal terminals extend to form a pair of second signal terminals, and the pair of first signal terminals and the pair of second signal terminals are configured for an external device to be plugged in.

11. The paddle device as claimed in claim 1, wherein the main board further comprises:
two pairs of conductive holes penetrating the surface layer and the specific layer so that the two terminals of the pair of second trace sections are electrically connected to the corresponding second terminals respectively.

12. The paddle device as claimed in claim 1, wherein the main board further comprises:
a pair of ground terminals disposed on the surface layer, and disposed on two sides of the plurality of second terminals of at least one terminal of the pair of second trace sections respectively, and
a ground region disposed on the surface layer, and electrically connected to the pair of ground terminals,
wherein the pair of ground terminals and the ground region surround the plurality of second terminals.

13. The paddle device as claimed in claim 1, wherein the main board further comprises:
a ground region disposed on the specific layer, and surrounding the pair of second trace sections.
